(19) United States
(12) Patent Application Publication
(10) Pub. No.: US 2008/0080266 A1
(43) Pub. Date: Apr. 3, 2008

(54) Memory driver circuits with embedded level shifters

(76) Inventors: Muhammad M. Khellah, Tigard, OR (US); Dinesh Somasekhar, Portland, OR (US); Yibin Ye, Portland, OR (US); Nam Sung Kim, Portland, OR (US); Vivek K. De, Beaverton, OR (US)

Correspondence Address: Buckley, Maschoff & Talwalkar LLC;Attorneys for Intel Corporation, Five Elm Street, New Canaan, CT, 06840, US

(21) Appl. No.: 11/527,782

(22) Filed: Sep. 27, 2006

(51) Int. Cl. G11C 7/00; G11C 5/14

(52) U.S. Cl. 365/189.11; 365/189.09

(57) ABSTRACT

A memory line driver system may include a first input line to receive a clock-gated signal associated with a first supply power level, a second input line to receive an information signal associated with a second supply power level, and an output to drive a memory cell line according to the first supply power level based on the clock-gated signal and the information signal.

### BACKGROUND

Conventional electronic memories may be implemented by arrays of discrete memory cells. Each memory cell in an array may store a value. Many systems exist for writing a value to and reading a value from a memory cell, most of which are based in part on the threshold voltages of transistors within the memory cell.

The scaling of transistor dimensions may result in unsuitably variable threshold voltages within adjacent transistors or memory cells. For example, mismatches in the threshold voltage between neighboring devices within a Static Random Access Memory (SRAM) cell may significantly reduce cell stability during a read operation or a write operation. Future process scaling will increase difficulties in complying with minimum cell stability requirements, since device parameter variations will likely become more pronounced.

Memory cell stability bears a direct relationship to supply voltage (Vcc). Accordingly, memory cells of low-power products exhibit less stability than identical memory cells of a higher-power product. Cell stability in low voltage operation can be improved by increasing the width of a memory cell area, which results in lower cache density. Other approaches have attempted to address low-power memory cell stability problem by using a higher supply voltage for a memory cell area and a lower supply voltage for other die areas. However, these other approaches may be unsuitable in terms of cell area, power consumption, and/or delay.

### BRIEF DESCRIPTION OF THE DRAWINGS

FIG. 1 is a block diagram of a memory according to some embodiments.

FIG. 2 is a block diagram of a memory line driver circuit according to some embodiments.

FIG. 3 is a schematic diagram of a conventional word line driver.

FIG. 4 is a schematic diagram of a word line driver according to some embodiments.

FIG. 5 is a schematic diagram of a conventional bit line driver.

FIG. 6 is a schematic diagram of a bit line driver according to some embodiments.

FIG. 7 is a block diagram of a system according to some embodiments.

### DETAILED DESCRIPTION

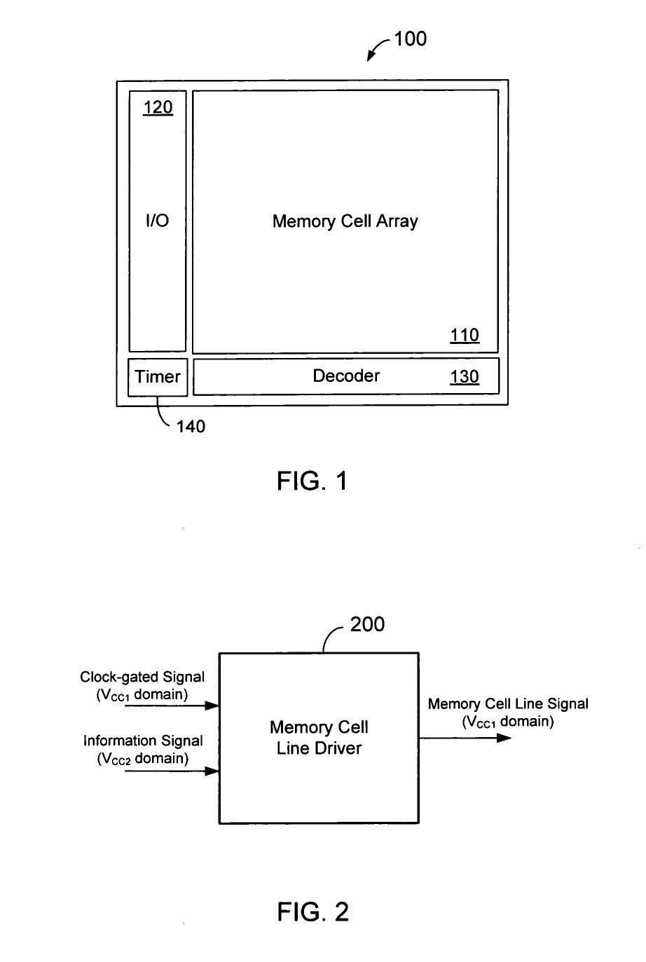

FIG. 1 is a block diagram of memory 100 according to some embodiments. Memory 100 includes memory cell array 110, I/O unit 120, horizontal decoder 130, and timer 140. Memory cell array 110 may include many memory cells of any type arranged in rows and columns. For example, a 32 kB memory cell array may include 256 columns and 128 rows of memory cells.

I/O unit 120 may include bit line drivers to write values to cells of an associated row of array 110. I/O unit 120 may also include sense amplifiers to determine voltage changes within associated rows of memory cell array 110, as well as devices to control pre-charging. Horizontal decoder 130 may include word line drivers to activate a column of memory cells array 110 based on a received x address. Timer 140 may provide clocking for various signals described herein.

According to some embodiments, memory cell array 110 is operated at a higher supply voltage (V_{LastLevelCache} or V_{LLC}) than surrounding functional blocks (e.g., other logic on the same chip). Since the surrounding blocks may operate at a lower V_{CC} (e.g., V_{CORE}), an interface between the blocks and array 110 provides signal translation from the lower supply voltage domain to the higher supply voltage domain. Such signal translation may be necessary to ensure correct operation of the logic (in case V_{CORE}<<V_{LLC}) and/or to prevent a short-circuit path in the receiving gate.

FIG. 2 is a block diagram of a memory cell line driver 200 to provide the aforementioned signal translation according to some embodiments. Memory cell line driver 200 may comprise a word line driver or a bit line driver according to some embodiments.

Memory cell line driver 200 includes a first input line to receive a clock-gated signal associated with a first supply power level (V_{CC1}), a second input line to receive an information signal associated with a second supply power level (V_{CC2}), and an output to drive a memory cell line according to the first supply power level (V_{CC1}) based on the clock-gated signal and the information signal. In some embodiments, the first supply power is greater than the second supply power.

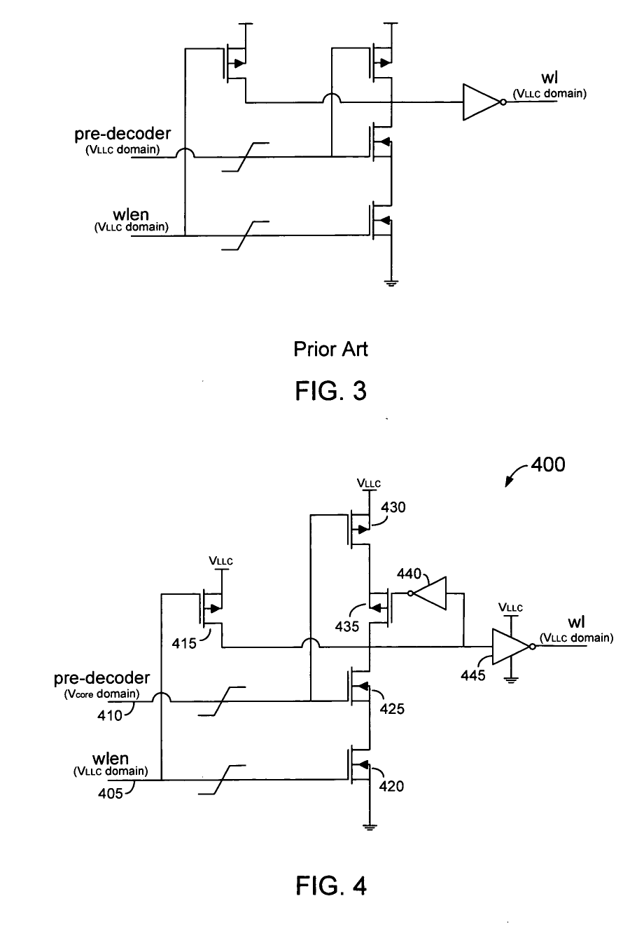

In some embodiments, memory cell line driver 200 comprises a word line driver, the clock-gated signal comprises a word line enable signal and the information signal comprises a pre-decoder signal. FIG. 3 is a schematic diagram of a prior art word line driver. As shown, a pre-decoder signal and a word line enable signal received by the prior art word line driver are associated with a same supply power level (i.e., V_{LLC}). Accordingly, the pre-decoder signal, which typically originates from an outside functional block operating at a lower supply power level (e.g., V_{CORE}), must be level-shifted (i.e., translated from the lower supply power domain) prior to receipt by the prior art word line driver.

FIG. 4 is a schematic diagram of word line driver 400 according to some embodiments. Word line driver 400 receives clock-gated signal wlen associated with the V_{LLC} domain on input line 405, and receives an information signal pre-decoder associated the V_{CORE} domain on input line 410. Word line driver 400 may drive a word line wl of memory cell array 110 according to the V_{LLC} domain based on the wlen signal and the pre-decoder signal.

More specifically, driver 400 includes p-type metal oxide semiconductor (PMOS) transistor 415, a gate of which is coupled to input line 405, and a source of which is coupled to V_{LLC}. A gate of n-type metal oxide semiconductor (NMOS) 420 is also coupled to the input line 405, and a source of NMOS transistor 420 is coupled to ground.

Input line 410 is coupled to a gate of NMOS transistor 425. A source of NMOS transistor 425 is coupled to a drain of NMOS transistor 420, and a drain of NMOS transistor coupled to a drain of PMOS transistor 415. PMOS transistor 430 includes a gate coupled to input line 410 and a source coupled to V_{LLC}. A source of PMOS transistor 435 is coupled to a drain of PMOS transistor 430. A drain of PMOS transistor 435 is coupled to a drain of NMOS transistor 420 and to a drain of PMOS transistor 415.

Circuit 400 also includes inverter 440. An input of inverter 440 is coupled to the drain of PMOS transistor 435, the drain of NMOS transistor 420 and the drain of PMOS transistor 415. An output of inverter 440 is coupled to a gate of PMOS transistor 435.

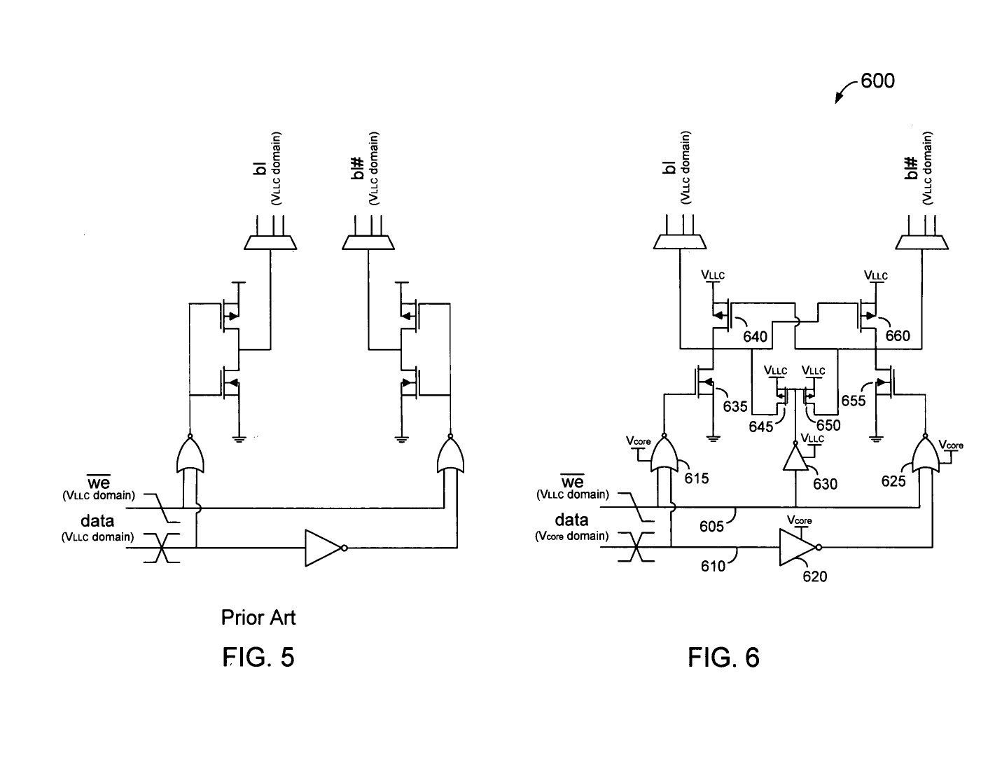

In some embodiments, memory cell line driver 200 of FIG. 2 comprises a write driver, the clock-gated signal comprises a write enable signal and the information signal comprises a data signal. FIG. 5 is a schematic diagram of a prior art write driver. The prior art write driver receives a data signal and a write enable signal, each of which is associated with a same supply power level (i.e., V_{LLC}). The data signal, which typically originates from a functional block outside of a memory, must therefore be level-shifted prior to receipt by the prior art write driver.

FIG. 6 is a schematic diagram of write driver 600 according to some embodiments. Write driver 600 receives clock-gated signal “we” associated with the V_{LLC} domain on input line 605, and receives an information signal “data” associated the V_{CORE} domain on input line 610. Write driver 600 may therefore drive a bit line bl of memory cell array 110 according to the V_{LLC} domain based on the “we” signal and the “data” signal. As described above, V_{LLC} may be greater than V_{CORE} in order to improve memory cell stability while minimizing an impact to total power consumption.

Driver 600 includes NOR gate 615 coupled to the V_{CORE} supply power, where a first input of NOR gate 615 is coupled to input line 605 and a second input of NOR gate 615 is coupled to input line 610. Accordingly, NOR gate 615 is to receive both the clock-gated signal “we” associated with the V_{LLC} domain, and the information signal “data” associated the V_{CORE} domain.

Driver 600 also includes inverter 620 coupled to the V_{CORE} supply power, with an input of inverter 620 coupled to input line 610. NOR gate 625 is also coupled to the V_{CORE} supply power. A first input of NOR gate 625 is coupled to input line 605 and a second input of NOR gate 625 is coupled to an output of inverter 620. Inverter 630 is coupled to the V_{LLC} supply power, and an input of inverter 630 is coupled to input line 610.

NMOS transistor 635 includes a gate coupled to an output of NOR gate 615 and a source transistor coupled to ground. A drain of PMOS transistor 640 is coupled to a drain of NMOS transistor 635 and a source of PMOS transistor 640 is coupled to the V_{LLC} supply power. A drain of PMOS transistor 645 is coupled to a drain of NMOS transistor 635 and to a drain of PMOS transistor 640. A gate of PMOS transistor 645 is coupled to an output of inverter 630, and a source of PMOS transistor 645 is coupled to the V_{LLC} supply power.

PMOS transistor 650 includes a drain coupled to a gate of PMOS transistor 640, a gate coupled to the output of inverter 630 and to the gate of PMOS transistor 645, and a source coupled to the V_{LLC} supply power. A gate of NMOS transistor 655 is coupled to an output of NOR gate 625, a source of NMOS transistor 655 is coupled to ground, and a drain of NMOS transistor 655 is coupled to the drain of PMOS transistor 650 and the gate of PMOS transistor 640. PMOS transistor 660 includes a drain coupled to a drain of NMOS transistor 655, a source coupled to the V_{LLC} supply power, and a gate coupled to the drain of PMOS transistor 645, the drain of NMOS transistor 635, and the drain of PMOS transistor 640.

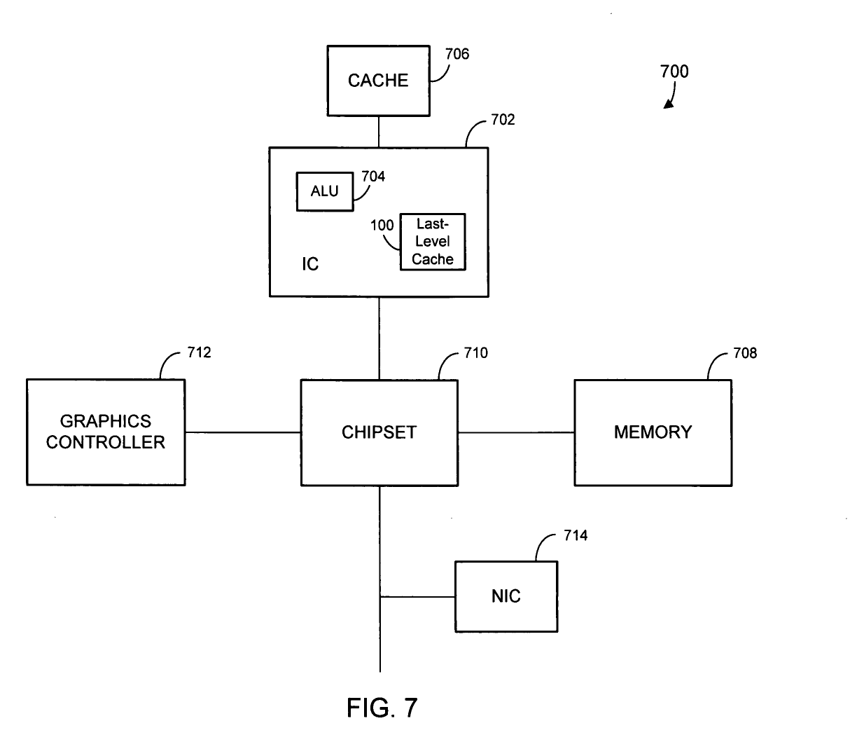

FIG. 7 illustrates a block diagram of system 700 according to some embodiments. System 700 includes integrated circuit 702 comprising sub-blocks such as arithmetic logic unit (ALU) 704 and memory 100 of FIG. 1, which serves as an on-die last-level cache. In some embodiments, sub-blocks such as ALU 704 operate in conjunction with a supply power that is lower than the supply power under which memory 100 operates. Integrated circuit 702 may be a microprocessor or another type of integrated circuit.

Integrated circuit 702 communicates with off-die cache 706 according to some embodiments. Off-die cache 706 may also comprise a memory such as memory 100. Integrated circuit 702 may communicate with system memory 708 via a host bus and chipset 710. System memory 708 may comprise any type of memory, including but not limited to Single Data Rate Random Access Memory and Double Data Rate Random Access Memory. Other off-die functional units, such as graphics controller 712 and Network Interface Controller (NIC) 714, may communicate with integrated circuit 702 via appropriate busses or ports.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A memory line driver circuit comprising:
a first input line to receive a clock-gated signal associated with a first supply power level;
a second input line to receive an information signal associated with a second supply power level; and
an output to drive a memory cell line according to the first supply power level based on the clock-gated signal and the information signal.

2. A circuit according to claim 1, wherein the first supply power is greater than the second supply power.

3. A circuit according to claim 1, further comprising:
a first PMOS transistor, a gate of the first PMOS transistor coupled to the first input line, and a source of the first PMOS transistor coupled to the first supply power;
a first NMOS transistor, a gate of the first NMOS transistor coupled to the first input line and a source of the first NMOS transistor coupled to ground;
a second NMOS transistor, a gate of the second NMOS transistor coupled to the second input line, a source of the second NMOS transistor coupled to a drain of the first NMOS transistor and a drain of the second NMOS transistor coupled to a drain of the first PMOS transistor;
a second PMOS transistor, a gate of the second PMOS transistor coupled to the second input line and a source of the second PMOS transistor coupled to the first supply power;
a third PMOS transistor, a source of the third PMOS transistor coupled to a drain of the second PMOS transistor, and a drain of the third PMOS transistor coupled to a drain of the first NMOS transistor and to a drain of the first PMOS transistor; and
an inverter, an input of the inverter coupled to the drain of the third PMOS transistor, the drain of the first NMOS transistor and the drain of the first PMOS transistor, and an output of the inverter coupled to a gate of the third PMOS transistor.

4. A circuit according to claim 1, wherein the clock-gated signal comprises a word line enable signal and the information signal comprises a pre-decoder signal.

5. A circuit according to claim 1, further comprising:
a first NOR gate coupled to the second supply power, a first input of the first NOR gate coupled to the first input line and a second input of the first NOR gate coupled to the second input line;
a first inverter coupled to the second supply power, an input of the inverter coupled to the second input line;
a second NOR gate coupled to the second supply power, a first input of the second NOR gate coupled to the first input line and a second input of the second NOR gate coupled to an output of the inverter;
a second inverter coupled to the first supply power, an input of the second inverter coupled to the first input line;
a first NMOS transistor, a gate of the first NMOS transistor coupled to an output of the first NOR gate and a source of the first NMOS transistor coupled to ground;
a first PMOS transistor, a drain of the first PMOS transistor coupled to a drain of the first NMOS transistor and a source of the first PMOS transistor coupled to the first supply power;
a second PMOS transistor, a drain of the second PMOS transistor coupled to a drain of the first NMOS transistor and to a drain of the first PMOS transistor, a gate of the second PMOS transistor coupled to an output of the second inverter, and a source of the second PMOS transistor coupled to the first supply power;
a third PMOS transistor, a drain of the third PMOS transistor coupled to a gate of the first PMOS transistor, a gate of the third PMOS transistor coupled to the output of the second inverter and the gate of the second PMOS transistor, and a source of the third PMOS transistor coupled to the first supply power;
a second NMOS transistor, a gate of the second NMOS transistor coupled to an output of the second NOR gate, a source of the second NMOS transistor coupled to ground, and a drain of the second NMOS transistor coupled to the drain of the third PMOS transistor and the gate of the first PMOS transistor; and
a fourth PMOS transistor, a drain of the fourth PMOS transistor coupled to a drain of the second NMOS transistor, a source of the fourth PMOS transistor coupled to the first supply power, and a gate of the fourth PMOS transistor coupled to the drain of the second PMOS transistor, the drain of the first NMOS transistor, and the drain of the first PMOS transistor.

6. A circuit according to claim 1, wherein the clock-gated signal comprises a write enable signal and the information signal comprises a data signal.

7. A system comprising:
a double data rate memory; and
a microprocessor in communication with the double data rate memory, wherein the microprocessor includes a memory line driver circuit comprising:
a first input line to receive a clock-gated signal associated with a first supply power level;
a second input line to receive an information signal associated with a second supply power level; and
an output to drive a memory cell line according to the first supply power level based on the clock-gated signal and the information signal.

8. A system according to claim 7, wherein the first supply power is greater than the second supply power.

9. A system according to claim 7, the memory line driver circuit further comprising:
a first PMOS transistor, a gate of the first PMOS transistor coupled to the first input line, and a source of the first PMOS transistor coupled to the first supply power;
a first NMOS transistor, a gate of the first NMOS transistor coupled to the first input line and a source of the first NMOS transistor coupled to ground;
a second NMOS transistor, a gate of the second NMOS transistor coupled to the second input line, a source of the second NMOS transistor coupled to a drain of the first NMOS transistor and a drain of the second NMOS transistor coupled to a drain of the first PMOS transistor;
a second PMOS transistor, a gate of the second PMOS transistor coupled to the second input line and a source of the second PMOS transistor coupled to the first supply power;
a third PMOS transistor, a source of the third PMOS transistor coupled to a drain of the second PMOS transistor, and a drain of the third PMOS transistor coupled to a drain of the first NMOS transistor and to a drain of the first PMOS transistor; and
an inverter, an input of the inverter coupled to the drain of the third PMOS transistor, the drain of the first NMOS transistor and the drain of the first PMOS transistor, and an output of the inverter coupled to a gate of the third PMOS transistor.

10. A system according to claim 7, wherein the clock-gated signal comprises a word line enable signal and the information signal comprises a pre-decoder signal.

11. A system according to claim 7, the memory line driver circuit further comprising:
a first NOR gate coupled to the second supply power, a first input of the first NOR gate coupled to the first input line and a second input of the first NOR gate coupled to the second input line;
a first inverter coupled to the second supply power, an input of the inverter coupled to the second input line;
a second NOR gate coupled to the second supply power, a first input of the second NOR gate coupled to the first input line and a second input of the second NOR gate coupled to an output of the inverter;
a second inverter coupled to the first supply power, an input of the second inverter coupled to the first input line;
a first NMOS transistor, a gate of the first NMOS transistor coupled to an output of the first NOR gate and a source of the first NMOS transistor coupled to ground;
a first PMOS transistor, a drain of the first PMOS transistor coupled to a drain of the first NMOS transistor and a source of the first PMOS transistor coupled to the first supply power;
a second PMOS transistor, a drain of the second PMOS transistor coupled to a drain of the first NMOS transistor and to a drain of the first PMOS transistor, a gate of the second PMOS transistor coupled to an output of the second inverter, and a source of the second PMOS transistor coupled to the first supply power;
a third PMOS transistor, a drain of the third PMOS transistor coupled to a gate of the first PMOS transistor, a gate of the third PMOS transistor coupled to the output of the second inverter and the gate of the second PMOS transistor, and a source of the third PMOS transistor coupled to the first supply power;
a second NMOS transistor, a gate of the second NMOS transistor coupled to an output of the second NOR gate, a source of the second NMOS transistor coupled to ground, and a drain of the second NMOS transistor coupled to the drain of the third PMOS transistor and the gate of the first PMOS transistor; and
a fourth PMOS transistor, a drain of the fourth PMOS transistor coupled to a drain of the second NMOS transistor, a source of the fourth PMOS transistor coupled to the first supply power, and a gate of the fourth PMOS transistor coupled to the drain of the second PMOS transistor, the drain of the first NMOS transistor, and the drain of the first PMOS transistor.

12. A system according to claim 7, wherein the clock-gated signal comprises a write enable signal and the information signal comprises a data signal.
